(19) United States
(12) Patent Application Publication
(10) Pub. No.: US 2025/0233043 A1
(43) Pub. Date: Jul. 17, 2025

(54) DEVICES AND METHODS INVOLVING GROWN DIAMOND IN A TEMPERATURE FIELD PLATE

(71) Applicant: The Board of Trustees of the Leland Stanford Junior University, Stanford, CA (US)

(72) Inventors: Srabanti Chowdhury, San Ramon, CA (US); Mohamadali Malakoutian, Stanford, CA (US)

(21) Appl. No.: 18/703,251

(22) PCT Filed: Oct. 28, 2022
(86) PCT No.: PCT/US2022/048218

§ 371 Date: Apr. 19, 2024

Related U.S. Application Data
(60) Provisional application No. 63/273,067, filed on Oct. 28, 2021.

(51) Int. Cl. H01L 23/373

(52) U.S. Cl. CPC H01L 23/3732

(57) ABSTRACT

In certain examples, methods and semiconductor structures are directed to a semiconductor device having a circuit that includes an active region (e.g., a channel region of a transistor) and having a poly crystalline-diamond-based thermal field plate (“TFP”). The TFP, or a first portion thereof, is oriented over or under the active region. Further, the first portion is located in proximity to the active region for passing heat away from the active region, and includes a layer of poly crystalline-diamond grains with an average grain width dimension and an average thickness dimension, wherein the average grain width dimension and the average thickness dimension characterize the poly crystalline-diamond grains as being more isotropic than columnar. With the first portion, or the entire TFP, being in close proximity of the channel region, during operation of the circuit, the TFP passes heat away from the channel region to maintain a relatively low-temperature circuit.

### FEDERALLY-SPONSORED RESEARCH AND DEVELOPMENT

This invention was made with Government support under contract N00014-19-1-2611 awarded by the Office of Naval Research. The Government has certain rights in the invention.

### BACKGROUND

Aspects of various embodiments are directed to semiconductor materials and devices which include diamond.

In exemplary contexts, aspects of the present disclosure are directed to semiconductors with self-heating portions of circuitry, such as transistor channels, and implementing diamond as part of the semiconductor device in a way to effectively remove heat from the self-heating portions. As high levels of heat during manufacturing of such semiconductors can degrade device performance and its lifetime (especially for high-power and high-frequency applications), in many applications it is important to grow the diamond at temperature levels within the tolerance levels of the semiconductor materials and circuits. High levels of heat during use of such semiconductors can also undermine semiconductors. For example, at high powers, excessive heat is often generated in semiconductor-device channels and this heat tends to increase the carrier scattering which in turn results in lower mobility. Also, during operation of optical-type semiconductor devices, heat generated in such devices can cause a shift in the wavelengths of the light being processed by the devices.

Moreover, for semiconductor devices which are designed to operate at high frequencies, due to the scaling, heat dissipation from the semiconductor channel is more challenging. Oftentimes, operating the semiconductor devices at high frequencies causes one or more high-temperature peaks. As one of various types of application-specific examples, such a heat removal technique may be used with diamond grown on high frequency high power GaN-type transistors such as those used in power amplifiers. Consider, GaN power amplifiers (PAs) which are sometime used as high-frequency high-power (HFHP)) transistor-based amplifiers. These types of PAs have become the preferred solution for base stations for 5G cellular communications, and also airborne and naval RADAR applications. These applications along with Terrestrial hub communications and Terrestrial backhaul communications with high power output (Pout)/element can generate severe levels of heat which creates significant challenges to the architecture and design.

These and other matters have presented challenges to efficient operation of semiconductor devices as used in a variety of applications.

### SUMMARY OF VARIOUS ASPECTS AND EXAMPLES

Various examples/embodiments presented by the present disclosure are directed to issues such as those addressed above and/or others which may become apparent from the following disclosure. For example, some of these disclosed aspects are directed to methods and semiconductor devices that use, and/or leverage from, maintaining low temperatures of the semiconductor devices during operation by use of grown diamond in close proximity to hot spots such as transistor channels and related circuitry.

In certain example embodiments, example aspects of the present disclosure are directed to methods involving use of and/or making semiconductor devices (in their entirety or part way through the manufacturing process), to systems for carrying out methods of manufacturing semiconductor devices, to methods of using semiconductor devices by their operation while dissipating heat therefrom, and/or to the semiconductor devices themselves.

In certain specific examples, the present disclosure concerns a semiconductor device having a circuit that includes a transistor with a channel region, and also having a polycrystalline-grown diamond-based thermal field plate (“TFP”). The TFP is characterized as having grown diamond being more isotropic than columnar and/or having a first portion located within 50 nm of the channel region, and/or as manifesting during operation of the transistor, a degree of thermal conductivity or of thermal boundary resistance, which is dependent on at least one diamond growth manifestation (e.g., near isotropic diamond grains and/or diamond grains which are more isotropic than columnar).

In other specific examples, the diamond may be grown to set the at least one diamond growth manifestation. With the first portion being within close proximity of the channel region during operation of the circuit, the TFP readily passes heat away from the channel region.

In above and/or other example embodiments, a semiconductor device and method involving such a device are directed to or involve the device comprising: a circuit including an active region; and a thermal field plate (“TFP”) having a first portion oriented over or under the active region. The first portion may be located in proximity to the active region for passing heat away from the active region, and the device may include a layer of polycrystalline-diamond grains with an average grain width dimension and an average thickness dimension, wherein the average grain width dimension and the average thickness dimension characterize the polycrystalline-diamond grains as being more isotropic than columnar.

In above and/or further specific experimental embodiments, the average grain width dimension is closer to the average thickness dimension than to twice the average thickness dimension, and the average grain width and average thickness dimensions characterize the layer of polycrystalline-diamond grains as approaching an ideal anisotropy ratio (e.g., an anisotropy ratio that is within approximately twelve percent of unity).

In the above and/or other specific experimental embodiments, a semiconductor device (e.g., from among the above types) may include an interlayer being located between the active region and the first portion of the TFP, and wherein the interlayer is to protect the active region while the layer of polycrystalline-diamond grains are being formed and to enhance adhesion of the layer of polycrystalline-diamond grains.

In yet further examples consistent with the above and/or other specific experimental embodiments, such a semiconductor device may include an interlayer between the channel region and the first portion of the TFP (e.g., to pass heat from the active region in a direction orthogonal to a plane along which the interlayer is situated), and a substrate adjacent the active region along a side of the active region that is opposite the interlayer; and/or include a substrate adjacent the active region along a side of the active region that is opposite the first portion of the TFP, wherein the substrate includes one or a combination of: silicon, or GaN, or Ga₂O₃, and InP; and/or the layer of polycrystalline-diamond grains may be formed to set, during operation of the transistor, a degree of thermal conductivity or of thermal boundary resistance, which is dependent on the polycrystalline-diamond grains as being more isotropic than columnar.

In other specific examples involving 3D heat mitigation and building on and/or consistent with one or more aspects of the above examples, the present disclosure is directed to a semiconductor device comprising: a circuit including an active region having one or multiple semiconductor layers, and including a gate extending towards or into the active region and further including source and drain regions on either side of the active region; an upper interlayer section over the active region and oriented with the one or multiple semiconductor layers being arranged as a stack of layers with each of the layers being oriented along a common first plane; at least one sidewall interlayer section respectively located along at least one side of the one or multiple semiconductor layers and oriented along another plane that intersects the common first plane; and a thermal field plate (“TFP”) having a top TFP section adhered to the upper interlayer section and at least one side TFP section respectively adhered to the at least one sidewall interlayer section. Each of the top TFP section and the at least one side TFP section may be located in proximity to the active region for passing heat away from the active region, and may include a layer of polycrystalline-diamond grains with an average grain width dimension and an average thickness dimension, which dimensions characterize the polycrystalline-diamond grains as being shaped to maximize, during operation of the circuit, in-plane thermal conductivity by the upper interlayer section along the common first plane and by the sidewall interlayer section along the other plane.

In yet other specific examples building on and/or consistent with one or more aspects of the above examples, the present disclosure is directed to a semiconductor device further including a substrate over which the circuit is situated, wherein the at least one sidewall interlayer section is to enhance adhesion of the polycrystalline-diamond grains and to pass the heat away from the active region and towards the substrate.

Consistent with the above exemplary aspects and devices, other example aspects of the present disclosure are directed to certain features of such a semiconductor device, wherein such features include one or more of the following: a gate adjacent the channel being formed as part of a layer including the TFP; and/or the first TFP portion (or one or more sections of the TFP) being oriented in a plane to provide in-plane thermal conductivity during operation of the transistor.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIGS. 1A and 1B are generalized cross-sectional diagrams showing respective example embodiments of a two-dimensional (2D) heat-spreading semiconductor device and a three-dimensional semiconductor device, according to the present disclosure;

FIGS. 2A and 2B are generalized cross-sectional diagrams showing respective example embodiments of a two-dimensional (2D) heat-spreading semiconductor device, modeling such a device as shown in FIG. 1A, and of a three-dimensional (3D) semiconductor device, modeling the device shown in FIG. 1B, according to the present disclosure;

FIGS. 3A and 3B are generalized cross-sectional diagrams showing respective example embodiments of a 2D heat-spreading semiconductor device at a different stage of manufacturing but related to the device shown in FIG. 2A and of a 3D semiconductor device at a later manufacturing stage related to the device shown in FIG. 2B, according to the present disclosure;

FIGS. 4A and 4B are respective top-down images of 3D heat-spreading semiconductor devices on a substrate, and FIG. 4C is a blown-up scanning electron microscopy (SEM) image of one of the semiconductor devices and showing top, side and bottom portions of the diamond-grown material, according to certain exemplary aspects of the present disclosure;

FIGS. 5A-5C depict aspects of an experimental semiconductor device, according to the present disclosure, with: FIG. 5A as a graph showing thermal barrier resistance (TBR) of a diamond-based GaN transistor versus substrate thickness, FIG. 5B representing transmission electron microscopy (TEM) images showing side views of a structure during manufacture processing, and FIG. 5C as a diagram showing a cross-sectional temperature profile across the device;

FIG. 5D as a graph showing anisotropy-ratio versus thickness for diamond-grown thermal field plates in accordance with an experimental semiconductor devices of the present disclosure;

FIG. 5E are images comparing more-conventional diamond grains having columnar structures with diamond grains having isotropic structures, with the right image in accordance with an experimental semiconductor device of the present disclosure;

FIG. 6 shows images for a comparison at interfaces for interlayer regions, according to an example of the present disclosure;

FIGS. 7A-7D illustrate temperature-related performance of experimental devices according to the present disclosure with FIG. 7A as a graph showing temperature versus distance of devices, and FIGS. 7B, 7C and 7D showing respective performance levels for such circuit portions without diamond (FIG. 7B), and with 1 micron of diamond grown for a 2D example (FIG. 7C) and for a 3D example (FIG. 7D); and

FIGS. 8A and 8B are flow diagrams respectively showing, for an experimental-specific example device according to the present disclosure, manufacture of a device in which the device or gate is processed before the diamond is grown (FIG. 8A), and a manufacture of a device in which the device or gate is processed after the diamond is grown (FIG. 8B);

FIGS. 9A and 9B are also flow diagrams showing more generalized flow corresponding to the experimental-specific example device shown in FIG. 8A and in FIG. 8B, with FIG. 9A showing device-first processing of a 3D heat-spreading device and FIG. 9B showing diamond-first processing of a 2D heat-spreading device; and

FIG. 10 is another flow diagram showing exemplary manufacturing flow for a 2D heat-spreading device and for a 3D heat-spreading device, also according to the present disclosure.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving growth and use of diamond in semiconductor devices such as those which may operate at high speeds and/or generate heat at such levels that aspects of the present disclosure would be readily recognized as benefiting such devices. While the following discussion presents certain examples using PC diamond for diamond layers in such devices, such discussion provide exemplary contexts to help explain such aspects and to enhance an understanding of the present disclosure. Accordingly, the present disclosure is not necessarily so limited.

In the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Exemplary aspects of the present disclosure are related to a method of manufacturing such a semiconductor device. One such method includes: forming a circuit that includes a transistor with a channel region; forming PC-grown diamond-based thermal field plate (“TFP”); and growing diamond for the TFP to set at least one diamond growth manifestation (e.g., a grain size), wherein the TFP is characterized as having a first portion located within 50 nm of the channel region and as manifesting during operation of the transistor, a degree of thermal conductivity or of thermal boundary resistance, which is dependent on the at least one diamond growth manifestation. Accordingly, during operation of the circuit, with the degree of thermal conductivity or of thermal boundary resistance being dependent as such and/or the diamond grains with an average grain width dimension and an average thickness dimension characterizing the polycrystalline-diamond grains as being more isotropic than columnar, the TFP passes heat away from the channel region at least at the first portion.

Consistent with the above device, other example aspect of the present disclosure are directed to certain features of such a semiconductor device, wherein such features include one or more of the following: a gate adjacent the channel being formed as part of a layer including the TFP; the diamond growth manifestation(s) including or referring to an average grain size in the first portion; the first TFP portion being oriented in a plane that runs in directions common to at least one direction in which the channel region runs, thereby situating the first portion of the TFP, relative to the channel, to provide practically ideal in-plane thermal conductivity during operation of the transistor.

Other aspects of such a semiconductor device, according to the present disclosure, are directed to one or more of the following: the first portion including nearly-isotropic diamond grains to reduce grain boundaries in a lateral direction relative to a plane along which the TFP (or in the case of a non-planar TFP, a portion of the TFP) is oriented; and the TFP including a second portion, and each of the first portion and the second portion including diamond grains having reduced grain boundaries, and the first portion and the second portion being providing optimized in-plane thermal conductivity during operation of the transistor, in three dimensions

Consistent with the above device, other example aspect of the present disclosure are directed to certain features of such a semiconductor device, wherein such features include one or more of the following: a gate adjacent the channel being formed as part of a layer including the TFP; the diamond growth manifestation(s) including or referring to an average grain size in the first portion and/or to an anisotropy ratio near unity; the first TFP portion being located over and preferably along a plane in which the channel region is situated, thereby situating the first portion of the TFP, relative to the channel, to provide in-plane thermal conductivity during operation of the transistor.

Other aspects of such a semiconductor device, according to the present disclosure, are directed to one or more of the following: a first TFP portion of a section of the TFP including nearly-isotropic diamond grains to reduce grain boundaries in a lateral direction relative to a plane along which the first portion of the TFP is oriented; and the TFP including a second section, and each of the first and second sections including diamond grains being oriented for reducing grain boundaries between one another, and the first and second sections being oriented to provide in-plane thermal conductivity during operation of the transistor, in three dimensions.

In yet other more specific examples, aspects of the present disclosure are directed to a heat removal technique for semiconductor devices and their circuitries by using a materials-integration interface layer (or “interlayer”) to integrate the grown diamond with an area of substrate on which one or more of the circuitries are formed, and the diamond may be located in close proximity to the heat-generating areas (e.g., hot spot) of the circuitries.

As one of various types of application-specific examples, such a heat removal technique may be used with diamond grown on high-frequency high-power GaN-type transistors such as those used in power amplifiers. In connection with certain experimental devices in which PC diamond is used as an interface-integration layer, a low thermal boundary resistance (e.g., “TBR” of less than 5-10 m2 K/GW) may be realized between the diamond and the GaN materials and with a high isotropy (e.g., less than ˜2.0) for formation of the diamond in close proximity of the transistor's channel where the generation of heat is concentrated.

Also in connection with certain experimental semiconductor devices during their operation, heat from hot spots (e.g., transistor channel regions) may be removed from the semiconductor devices in vertical and both lateral directions (that is, 3D heat extraction). In a more specific example experimental semiconductor device involving a GaN-type transistor, diamond was grown to form a thermal field plate located near such hot spots so to realize 3D heat extraction from the GaN-type transistor with the lowest thermal boundary resistance (TBR) of 3.1 m2 K/GW between diamond and the GaN-type transistor and a maximized isotropy and within 1 μm of (diamond's) thickness from the channel. The devices may be fabricated with diamond deposited on top of the device and on the sidewalls such that heat can be removed from all three dimensions. Such a maximized isotropy has been demonstrated experimentally, in efforts according to examples of the present disclosure, as corresponding to an anisotropy ratio of approximately 1.12 or better, where the anisotropy ratio is defined as the average thickness dimension divided by the average grain width dimension (the average grain width dimension being in a direction over or generally parallel to a layer of the active region or to a first plane along which the TFP, or a first portion of the TFP, is formed as a layer, and the average thickness dimension being in a direction which may extend direction in direction orthogonal relative to the interlayer or first plane).

In yet another example, a diamond (e.g., as a layer) is used in the device so as to provide a thermal conductivity which is dependent on an average grain size associated with the diamond. The thermal conductivity of the diamond layer is in the range of 100-2000 W/mK. For example, by locating the diamond around the device in more than two dimensions, channel thermal resistance is reduced, and this eventually lowers a high temperature peak in the channel and flattens the temperature profile associated with said at least one of the one or more semiconductor devices.

In a method of manufacturing or treating a semiconductor device (e.g., associated with one of the above semiconductor devices), the diamond or diamond layer is added after a remaining portion of the semiconductor device is otherwise fabricated (e.g., ready to be tested). This may be realized, for example, by chemical vapor deposition of PC diamond and/or by a single (adding of the diamond) step.

In another example, a semiconductor device (e.g., associated with one of the above semiconductor devices) is characterized as operating at high switching speeds wherein such speeds are at least partially attributable to use of a technology (e.g., GaN, Ga2O3, InP) used in the semiconductor device and causing a hot spot in the semiconductor device to generate heat. Further, in certain more specific examples, one or more of the semiconductor devices is characterized as having at least one of the following properties due to dissipation of heat from a hot spot in the semiconductor device by use of diamond, wherein the properties are: an anisotropy ratio of 1.12 (approximately twelve percent of unity); a very low thermal boundary resistance or “TBR” (e.g., the above-noted TBR of 3.1 m²k/GW); and significantly-high thermal conductivity “TC” of about 637 W/mk (e.g., ˜10-15% of this level, and in some instances reaching or this level slightly.

Consistent with the above aspects, such a manufactured device or method of such manufacture may involve aspects presented and claimed in U.S. Provisional Application Ser. No. 63/273,067 filed on Oct. 28, 2021 (STFD.436P1 S21-331) with Appendices A and B, and to which priority is claimed. To the extent permitted, such subject matter is incorporated by reference in its entirety generally and to the extent that further aspects and examples (such as experimental and/more-detailed embodiments) may be useful to supplement and/or clarify.

Various experimental (proof-of-concept) examples, some of which are discussed hereinbelow, have demonstrated that the above-characterized aspects, structures and methodologies may be used in one or more semiconductive devices to form semiconductor circuits and devices including but not limited to the specific types of material layers, applications and geometries used in such experimental examples.

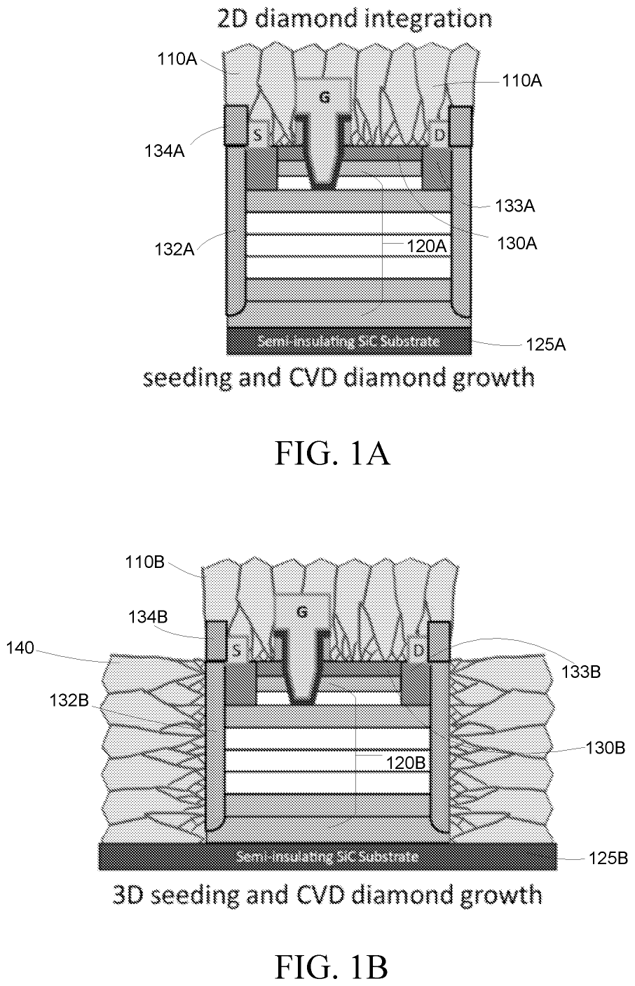

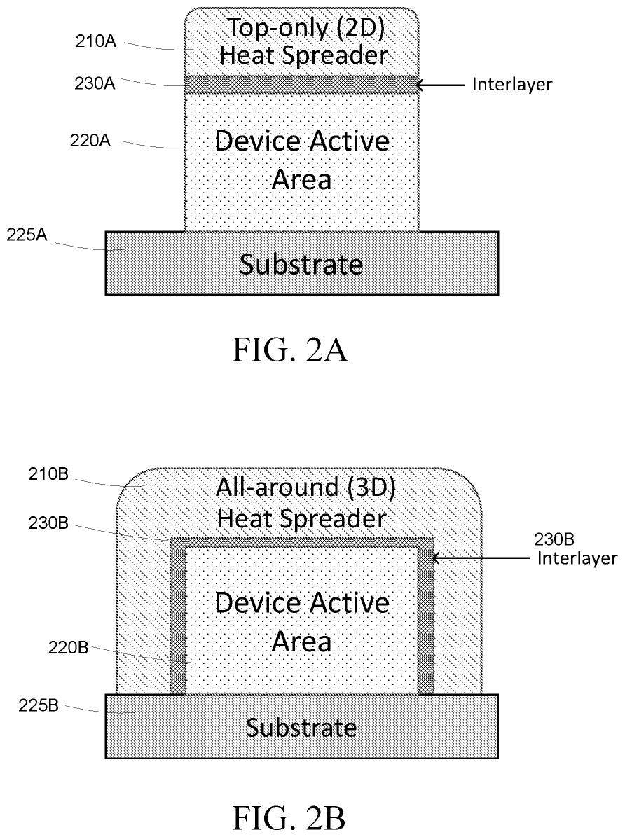

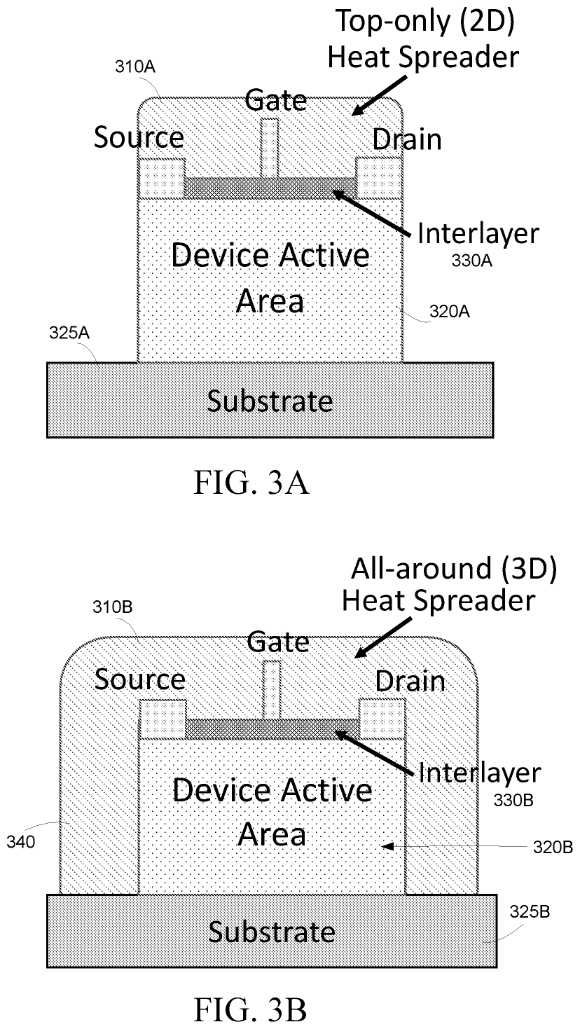

FIGS. 1A and 1B are generalized cross-sectional diagrams showing respective example experimental embodiments of semiconductor devices according to exemplary aspects of the present disclosure. FIG. 1A is a cross-sectional diagram of an experimental 2D heat-spreading semiconductor device, and FIG. 1B is a cross-sectional diagram of an experimental 3D semiconductor device. The reference identifiers used in FIGS. 1A and 1B correspond to each other for similar aspects, and these reference identifiers are also chosen to correspond to similar aspects in FIGS. 2A, 2B, 3A and 3B (e.g., 110A corresponding to 110B, 210A, 310A and 310B, 125A corresponding to 125B, 225A, 325A and 325B, etc.).

Shown in each of FIGS. 1A and 1B is an upper heat-spreading diamond-grown layer 110A or 110B, and an interlayer 130A or 130B, an active area of the device (or device active area) 120A or 120B, and a semi-insulating substrate 125A and 125B. Interlayers 130A and 130B may be composed of a material (e.g., SiN) to provide protection of an active area of the device (or device active area) 120A or 120B during one or more manufacturing processing steps of the corresponding device such as during growth of the diamond layer 110A and 110B. As shown, each of device active areas 120A and 120B may be implemented by one layer or multiple layers formed over one another.

Interlayers 130A and 130B are shown as an upper (horizontally-oriented) layer over the device active areas 120A and 120B. However, the interlayers 130A and 130B may also be implemented to provide such protection by surrounding the (vertically-oriented) sides 132A and 132B along the device active areas 120A and 120B. The device active areas of each of FIGS. 1A and 1B are part of a transistor which also includes gate (G) and source(S) and drain (D) regions, respectively depicted in each of FIGS. 1A and 1B as G, S and D. As may be appreciated in these contexts and in such description of a generic a transistor structure, the terms “source” and “drain” may be used interchangeably with source and/or drain referring to drain and/or source. Regions under and around the gate (G) and between the source and drain form the transistor channel region at which generation of heat may be most concentrated. In this particular experimental example, contacts 133A and 133B are formed before the source(S) and drain (D) are formed, and pads 134A and 134B may be formed adjacent the gate and source for access thereto by other circuitry in the semiconductor device.

The main distinction between FIGS. 1A and 1B is that FIG. 1A shows a diamond layer 110A grown in two dimensions (e.g., along an X-Y plane substantially parallel to a plane along a top surface of the interlayer 130A or of the substrate 125A), whereas FIG. 1B shows such a two-dimensional diamond layer 110A, 110B and also a heat-spreading diamond layer 140 surrounding a portion, most or all of the (vertically-oriented) sides of the device active areas 120A and 120B. During operation of transistors, the device active areas 120A and 120B often represent the most-significant heat-producing regions of the device and therefore, optimizing use of the heat-spreading diamond layer 140 by using it to surround the device active areas 120A and 120B in this manner and with at least a portion in close proximity (e.g., a horizontal-oriented portion over and nearest the hot spot or channel being located within 2-50 nm of the channel region) to the device active areas 120A and 120B has been shown to be extremely effective in passing the generated heat away from the device active areas 120A and 120B.

According to one specific aspect of the present disclosure, semiconductor devices such as shown in FIGS. 1A and 1B may be made by forming a transistor-based circuit (i.e., that includes a transistor with a channel region); and then forming or growing PC-diamond-based thermal field plate (“TFP”) characterized as having a first portion (the upper layer) located within 2-50 nm of the channel region and as manifesting during operation of the transistor, a degree of thermal conductivity or of thermal boundary resistance, which is dependent on at least one growth manifestation of the diamond. As shown in FIGS. 1A and 1B, the TFP may correspond to 110A of FIG. 1A, and in of FIG. 1B, 110B and/or 140. The interlayer 130A of FIG. 1A or 130B of FIG. 1B may be formed before the TFP to provide protection of the device active area (and channel region).

In connection with the present disclosure, it has been discovered that by growing diamond for the TFP to set the at least one diamond growth manifestation for the diamond grains (depicted collectively as forming each of layers 110A, 110B and 140, during operation of the circuit, the TFP is most effective in passing heat away from the channel region. In one more-particular example embodiment, the diamond for the TFP is grown to set (as one or more diamond growth manifestations) an average grain size in a first TFP portion (e.g., closest to the center of the channel) for the diamond grains and/or the diamond grains being nearly isotropic to reduce grain boundaries in a lateral direction relative to a plane along which the first portion of the TFP is grown and formed. As in each of FIGS. 1A and 1B, the depicted grains are shown (although not to scale) to be as large as practical and with the diamond grains of the layers 110A and 110B shown to be grown via a high lateral growth rate so as to result in a wider grain (in the lateral direction) relative to a plane along which the first portion of the TFP is grown or formed.

Similarly, in the 3D implementation of FIG. 1B, the depicted grains forming the grown diamond 140 are shown to be as large as practical (e.g., measured by way of average grain size) and with the diamond grains of the TFP 110A and 110B shown to have a relative wide configuration relative to a plane along which the TFP is formed. This reduces grain boundaries in the lateral direction, and as noted above, increases the effectiveness in passing heat away from the channel region.

Substantially corresponding to FIGS. 1A and 1B, FIGS. 2A and 2B and FIGS. 3A and 3B are block-like or modeled diagrams of the example embodiments of 2D-type and 3D-type heat-spreading semiconductor devices. Each of FIGS. 2A and 2B shows such a 2D-type or 3D-type device (without depicting the gate, source drain terminals of FIGS. 1A and 1B hidden). The 2D-type device of FIG. 2A is shown as including a top-only heat spreader or TFP 210A, an interlayer 215A, the device active area 220A and the substrate 225A. The 3D-type device of FIG. 2B shows each of these structures respectively as 210B, 215B, 220B and 225B. The difference between the device of FIG. 2A and of FIG. 2B (similarly with the difference noted above between FIG. 1A and FIG. 1B) is that the device of FIG. 2A has diamond grown in a section which is only along the horizontal upper (top) surface 210B which is over or substantially parallel to the substrate 225B, whereas the device of FIG. 2B also has diamond grown on the upper surface 210B and both sides (or all around) the active area. In each of these 2D and 3D-type devices, at least one portion of the diamond is situated in close proximity to the device active area, to increase the ability to pull heat away from the device. Moreover, with a larger average grain size, this ability is further enhanced.

The modeled devices of FIGS. 3A and 3B correspond to the modeled devices of FIGS. 2A and 2B but with FIGS. 3A and 3B also showing the gate, source and drain of the respective devices of FIGS. 1A and 1B. As noted above, the reference identifiers in these above-noted figures track with one another for simplifying discussion. For example, the device of FIG. 3A models a 2D heat-spreading device with 2D diamond layer or TFP 310A (similar to the 2D heat-spreading device of FIG. 2A via 2D diamond layer or TFP 210A), and the device of FIG. 3B models a 3D heat-spreading device via diamond portions 310B and 340 (similar to the 3D heat-spreading device of FIG. 2B via diamond portions on top and sides).

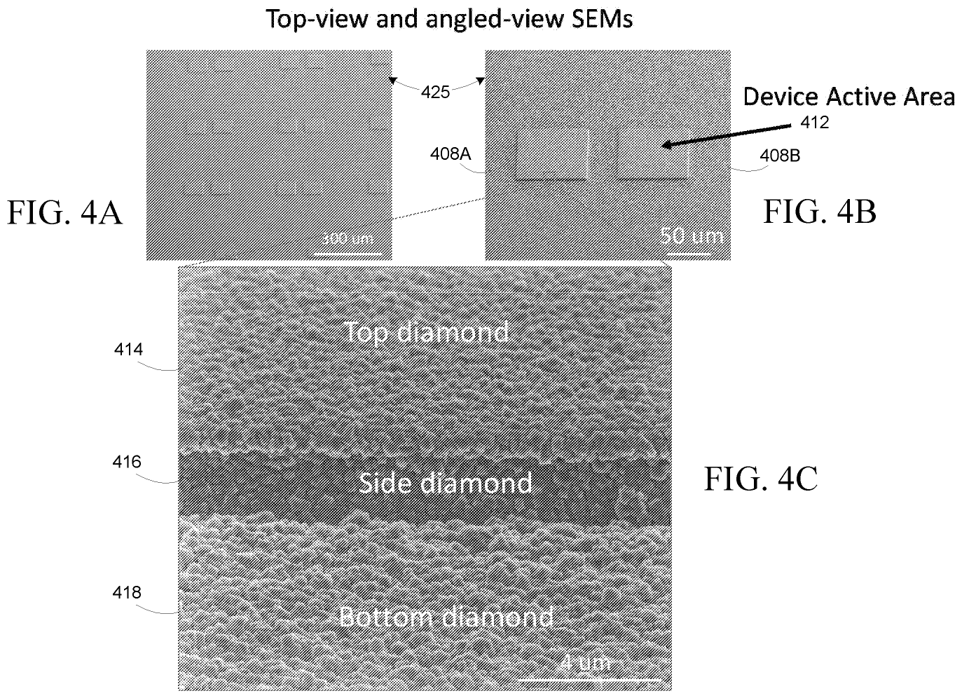

FIGS. 4A and 4B are respective top-down SEM images of 3D heat-spreading semiconductor devices 408A, 408B, etc. formed on a substrate 425. From a top-down perspective, the device active area 412 in one of the semiconductor devices is located under an upper (horizontally-oriented) diamond layer. As shown in FIG. 4B, dimensions are shown with the scale bar being fifty (50) microns.

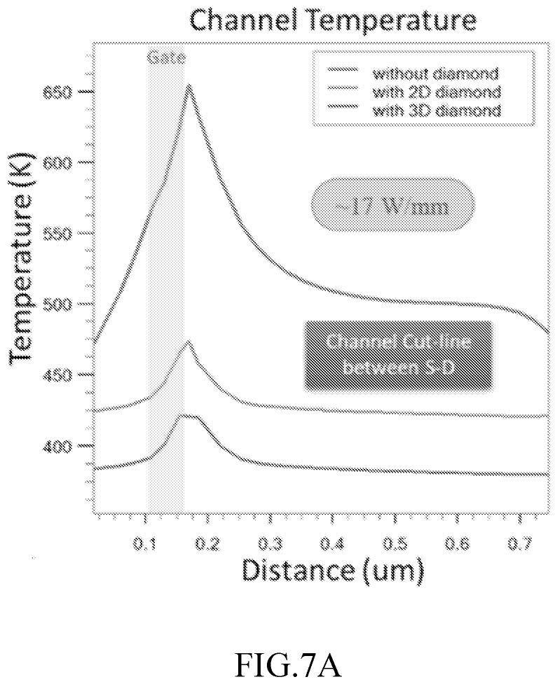

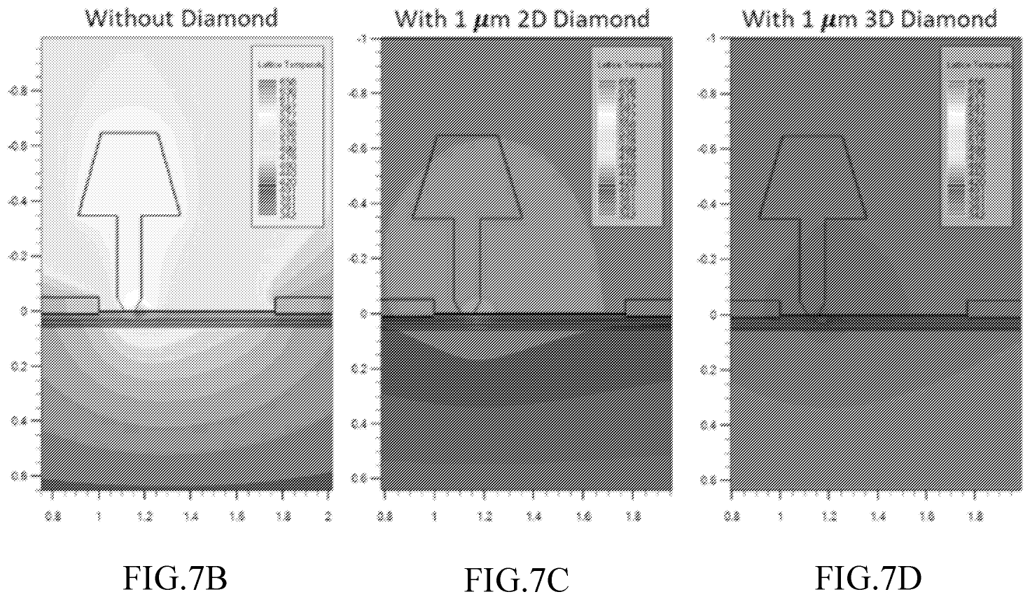

FIG. 4C is a blown-up SEM image of an experimental semiconductor device showing a side cross-sectional view of the diamond for such a 3D heat-spreading semiconductor devices as device 408A or 408B. Again from a side perspective (e.g., looking at the cross section from a plane parallel to the substrate 325B of FIG. 3B), a top or upper (horizontally-oriented) portion of the diamond layer is shown at 414, a middle section of the diamond-grown material is shown at 416 and a lower section of the diamond-grown material is shown at 418. The middle section 416 of the diamond-grown material is closest to the interlayer such as interlayer 330B of FIG. 3B. In each of the 2D and 3D heat-spreading devices, experiments according to the present disclosure advantageously demonstrate that a top-side diamond integration, when placed in close proximity (e.g., within nanometers) of the channel (or hotspot) helps not only to reduce the temperature peak in the channel (with the heat sink at the bottom of the wafer) but also the average channel temperature as demonstrated in the simulations (such as discussed infra in connection with FIGS. 7C, 7D).

As can be seen in these SEM images of FIGS. 4A, 4B and 4C, diamond has been nucleated conformally not only on top but also on the side-wall with a variety of different angles, which provides a continuous heat path from the active area to the substrate for removing the heat efficiently.

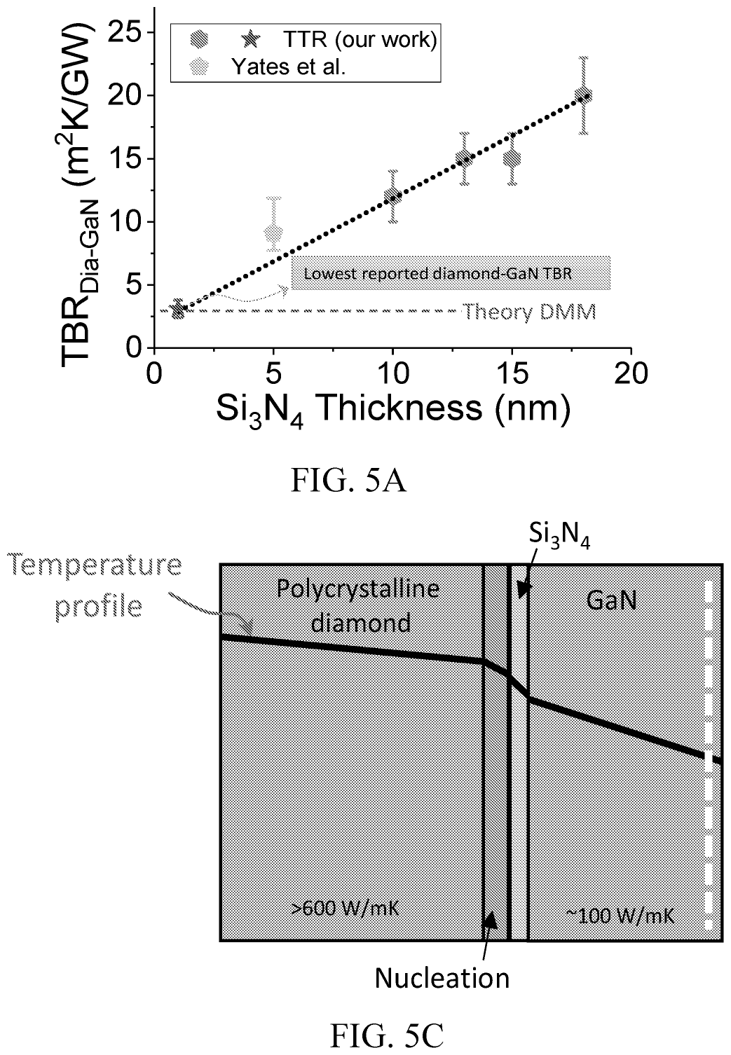

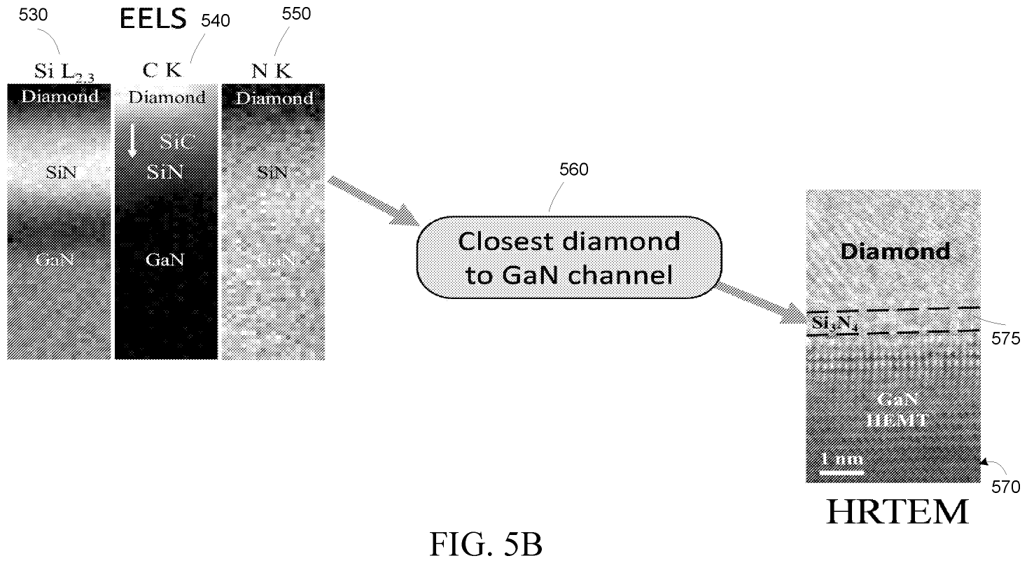

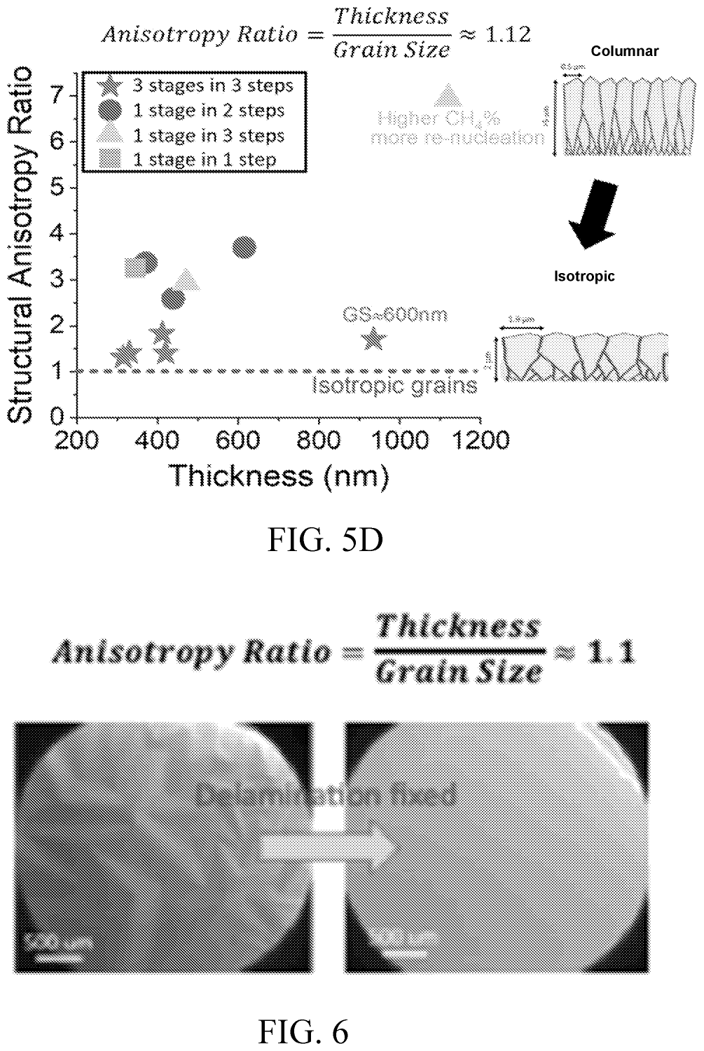

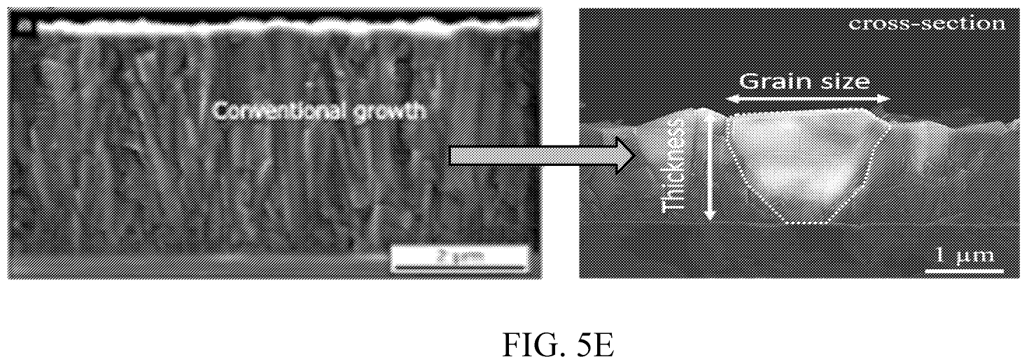

Also according to the present disclosure, FIGS. 5A-5D depict aspects of a particular example experimental GaN-type transistor device which uses SiN (e.g., Si₃N₄) as one of many example materials for a dielectric interlayer. FIG. 5A is a graph showing thermal barrier resistance (TBR) of a diamond-based GaN transistor versus substrate thickness. In FIG. 5A, the thermal boundary resistance between diamond and GaN including the Si₃N₄ interlayer (lumped TBR) was measured using time-domain-thermoreflectance (TDTR) and transient-thermoreflectance (TTR). As shown in this graph of FIG. 5A, controlling the etch rate with angstrom-range resolution resulted in a less-than one (1) nm interlayer (corresponding to the lowest reported TBR in the literature as 3.1 m²K/GW; see the (reddish) star-shaped data point in FIG. 5A which is very close to the theoretical value predicted using a diffuse-mismatch model.

FIG. 5B shows a high-resolution transmission electron microscopy (HRTEM) image for a cross-section view of the sample that resulted in the lowest TBR. The illustration of FIG. 5B corresponds to manufacture processing with occurrence of significant thinning of an (Si3N4) interlayer in connection with diamond growth using a controlled growth rate method involving etching of the interlayer (e.g., via a first stage of growth as discussed below with FIG. 5D). The HRTEM imaging shows how much of the Si3N4 interlayer remains after the diamond growth. The left of FIG. 5B depicts an EELS (Electron Energy Loss Spectroscopy) result, with the three side-by-side images 530, 540 and 550 showing progression (from left to right) of how carbon diffuses inside the Si₃N₄ (as more depicted generally at 560 and 570) to change the interface into an SiC ultrathin (interfacial) layer 575, and to realize the diamond in close proximity to the GaN channel. In related experimental efforts, it has been shown that the carbon diffusion into the Si₃N₄ changes the interface to SiC to manifest a much higher thermal conductivity (TC) than Si₃N₄. Since SiC has a higher TC compared to Si₃N₄ it provides lower thermal resistance in the interface which reduces TBR even more. As indicated above, this progression and result may be realized by carefully controlling the etch and growth rates.

FIG. 5C is a diagram showing a cross-sectional temperature profile across such a device as referred to in connection with FIGS. 5A and 5B. More specifically, FIG. 5C shows advantages for certain example embodiments, in that controlling the etch-growth rate to reduce the thickness of nucleation layer and interlayer dielectrics can result in a decrease of temperature discontinuity at the interface and ultimately the TBR between diamond and device channel. Basically, the nucleation layer and the interlayer (or in this example, the interlayer dielectric) are required for protection of the underlying semiconductor material, and strong adhesion (these layers also help for starting the diamond growth on a foreign material).

FIG. 5D as a graph showing anisotropy-ratio (in a ratio between diamond thickness and its grain size) versus thickness for a diamond-grown thermal field plate as implemented in connection with different experimental examples according to the present disclosure. According to certain exemplary aspects, advancements of the present disclosure leverage from using a more isotropic (closer to unity) diamond situated near the active region. Since diamond has an anisotropic nature in terms of its TC (thermal conductivity) parameters in lateral and vertical directions, by having such a diamond layer that is more isotropic than columnar, the effective TC is enhanced due to higher in-plane TC. This effective TC is linked with a higher lateral growth rate for more-isotropic grains (sketch at lower right of FIG. 5D) compared to conventional grains having a more-columnar structures (sketch at upper right of FIG. 5D). In one example, such illustrated (sketched) more-isotropic grains may represent a first portion of the TFP, with the active region oriented over an interlayer oriented along a planar direction. With such polycrystalline-diamond grains in the first portion being more isotropic than columnar, grain boundaries between the polycrystalline-diamond grains along lateral sides between the grains are reduced (or minimized) relative to grain boundaries in grains that are more-columnar.

More particularly, in connection with various experiments leading to present disclosure, FIG. 5D plots four different types of diamond growth, categorized in one-to-three growth stages associated with one-to-three steps (depending on the type and/or stage of growth). The lower (star-shaped) plots in FIG. 5D correspond to a high-lateral growth type resulting in the most isotropic grains (smaller anisotropy ratio), with the three other types of growth corresponding to circular-, triangular- and square-shaped plots being linked with less isotropic grains (larger anisotropy ratio). The three stages may be categorized in three growth stages: an initial nucleation stage which may involve a step of increased/higher percentages of CH₄ for re-nucleation (as shown in FIG. 5D), a final stage where growth is finalized, and an intermediate stage spanning the growth between the initial and final stages.

The steps corresponding to such growth may be defined as a function of typical diamond growth parameters (e.g., growth temperature, plasma power, gas pressure and chemistry used for each type of semiconductor) and the first step is related to and is best appreciated from a review of such growth parameters in view of the roles of the interlayer. The interlayer, which may be realized via ion implantation of an appropriately-chosen semiconductor material, is useful in protecting the (layer(s) of the) active area during growth of the diamond grains and in enhancing adhesion of the diamond grains to the semiconductor material. The first step, occurring in the initial diamond growth stage, involves adjusting the parameters for a high-temperature hydrogen plasma. With accurate controls over etching of the interlayer, the first step involves high-temperature hydrogen plasma to reduce the thickness of the interlayer so as to render a thin interlayer of dielectric material (e.g., sufficiently-thin to form the diamond as close as possible to the active area, but not so thin to etch completely through the interlayer which is to adhere the diamond to the semiconductor material below). In this first step and as may be gleaned from FIG. 5D, more re-nucleation (high CH₄) may be used to grow and integrate the diamond quickly to help protect the remaining interlayer and the semiconductor material underneath.

After the first stage, the subsequent steps are to transition and/or set the growth parameters for the type of semiconductors used for the desired level of diamond growth. The controls of the diamond growth chamber may be swept (for the type of semiconductor wafer on which the diamond is grown) to effect a preferred combination of these parameters to cause sufficiently high lateral growth rates to meet certain specifications (e.g., minimal thermal conductivity for the design as a function of the anisotropy ratio). Accordingly, at least second/or third steps involve setting the controls on the chamber (in which the diamond is grown) to initiate and/or facilitate higher lateral growth to result in diamond grains that are more isotropic than the columnar structure of conventional diamond grains, as depicted in FIG. 5D. For example, while the first step may be maintaining the significantly reduced temperature relative to that used for high-temperature hydrogen plasma (e.g., reduced to a temperature in a wide range from a few hundred to one thousand degrees centigrade), the second and third steps may be found by sweeping controls for plasma power and for gas pressure (and comparing results) to learn a preferred higher power and/or pressure so as to realize the desired high-lateral growth rates (and/or anisotropy ratio) in these two latter growth stages. As in connection with the particular experimental examples linked to the lower (star-shaped) plots in FIG. 5D, a higher power and/or pressure as second and third steps during the intermediate and final stages show a resultant increase in the lateral growth rate.

FIG. 5E are images comparing more-conventional diamond grains having columnar structures with diamond grains having isotropic structures, with the right image in accordance with an experimental semiconductor device of the present disclosure. The more isotropic diamond grains as shown in the right image of FIG. 5E may represent the diamond across the TFP (or at least a portion or section of the TFP such as a first TFP section as in 110B of FIG. 1B which is oriented in a direction along a first plane) and may also represent the diamond across another part of the TFP (or at least a portion or section thereof such as a second TFP section as being along one side or all around the sides of the active region 120B of FIG. 1B which is oriented in a direction along a plane that is orthogonal to or intersects with the first plane). For the first portion and the second portion, polycrystalline-diamond grains are more isotropic than columnar to minimize or reduce such grain boundaries between the polycrystalline-diamond grains, and/or to maximize in-plane thermal conductivity during operation of the circuit.

Demonstrating the importance of these roles of the interlayer, FIG. 6 shows a pair of SEM images (from top of respective diamond samples) for a comparison at interfaces or respective interlayer regions, with the first image showing delamination due to high residual thermal stress at the interface and the second image showing a mitigation of the residual stress to avoid delamination at the interface between diamond and the underlying semiconductor material. High residual stress in the diamond layer may occur after the growth when the sample is cooling down to room temperature from 600-700 C temperature due the mismatch in coefficient of thermal expansion between diamond and the substrate. By adjusting the nucleation technique and modifying the interlayer material and thickness (e.g., as discussed above in connection with FIG. 5D), mitigating of the residual stress and preventing diamond delamination can be achieved.

According to specific example embodiments involving GaN as an exemplary underlying semiconductor material, the interlayer carries the roles of integrating the diamond, protecting the underlying GaN material (e.g., the (GaN) channel of the transistor or device active area) from damage such as decomposition/delamination, and enhancing the diamond adhesion by formation of SiN.

Tracking with the sketches respectively shown in the upper right and lower right of FIG. 5D, FIG. 5E provides respective SEM images showing cross-sectional perspectives of a set of more-columnar grains (conventional as in left image) and a set of more-isotropic grains (right image) according to an example of the present disclosure. For more information regarding image showing a set of more-columnar grains, reference may be made to J. Appl. Phys. 119, 175103 (2016), from which the left image is adapted. To reach a certain TC, a TFP such a columnar structure would need a layer that is significantly thicker than corresponding examples of the present disclosure.

The image on the left of FIG. 5E (corresponding to the sketch in the upper right of FIG. 5D), shows a cross section of more-columnar structures with an anisotropy ratio of greater than ten (10) which manifests a relatively low in-plane thermal conductivity. In contrast, the image on the right of FIG. 5E (corresponding to the sketch in the lower right of FIG. 5D), shows a cross section of near-isotropic diamond gains as developed in connection with an experimental semiconductor device of the present disclosure. In each of the images of FIG. 5E (and the sketches of FIG. 5D), the “grain size” is the horizontal dimension shown along the top of one such grain, and the grain thickness is from the vertical or orthogonal dimension between bottom and top surfaces of the grain. The scale of the left SEM image of FIG. 5E is shown in the lower right corner with the bar length corresponding to 2 microns (˜500 nm grain size with >5 micron thickness), whereas the scale of the right SEM image is shown in the lower right corner with the bar length corresponding to 1 micron.

For certain of the above examples in accordance with the present disclosure, the diamond growth technique realizes an anisotropy ratio of ˜1.12 which is extremely close to the ideal goal of unity for highest TC with this grain size. Moreover, in accordance with the present disclosure, growing a very thick layer to reach a certain TC value is not necessary. With such approaches according to the present disclosure, a higher lateral growth rate leads to more near isotropic grain, which permits energy (phonons) to travel in the lateral direction with less (phonon) scattering sites (grain boundaries), and in turn this enhances their cooling capabilities.

FIGS. 7A-7D illustrate temperature-related performance of experimental devices according to the present disclosure, via laboratory tests. FIGS. 7B, 7C and 7D are TCAD electro-thermal simulations (generated via Silvaco-TCAD) to predict channel temperature while each of three HEMPT devices with 45 nm L_{g} is operating at 17 W/mm. FIG. 7A is a graph showing temperature versus distance plots of the three devices (not shown) with similarly-constructed circuit portions without diamond as may be conventional and with diamond according to examples of the present disclosure. In such devices with the PC diamond forming the conduit for conveying the heat to the bottom heat sink, these plots show the reduction in the peak temperature as well as the average channel temperature with the heat sink at the bottom of the wafer.

As represented in FIGS. 7A through 7D, the reduction in the average channel temperature (what we refer to as the thermal field plating effect) is as significant as the reduction of the peak and should be noted as an outcome of the diamond integration approach according to such examples of the present disclosure. FIG. 7A shows, on the upper plot, temperature versus distance plotted for such a circuit portion without diamond, which corresponds to the simulation depicted at FIG. 7B. On the middle plot, FIG. 7A shows temperature versus distance plotted for such circuit portions with 1 micron of diamond grown for a 2D diamond configuration (diamond over the top of the active area), which corresponds to the simulation depicted at FIG. 7C. On the lowest plot, FIG. 7A shows temperature versus distance plotted for such circuit portions with 1 micron of diamond grown for a 3D diamond configuration (diamond all-around the active area), which corresponds to the simulation depicted at FIG. 7D. A 2D temperature mapping profile confirms how diamond can be used in this manner to spread away from the channel and lower the temperature for better performance.

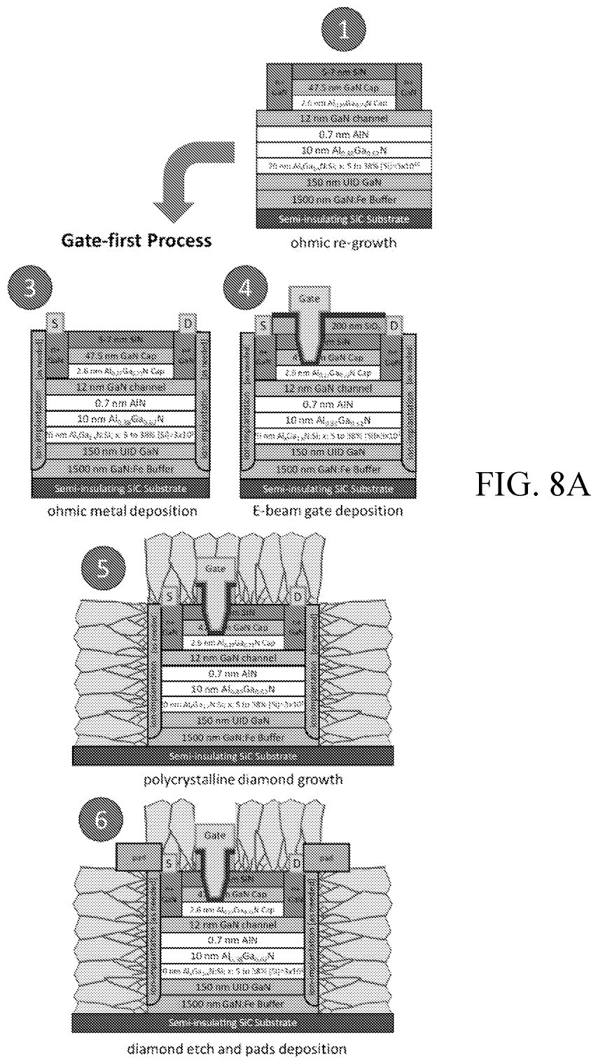

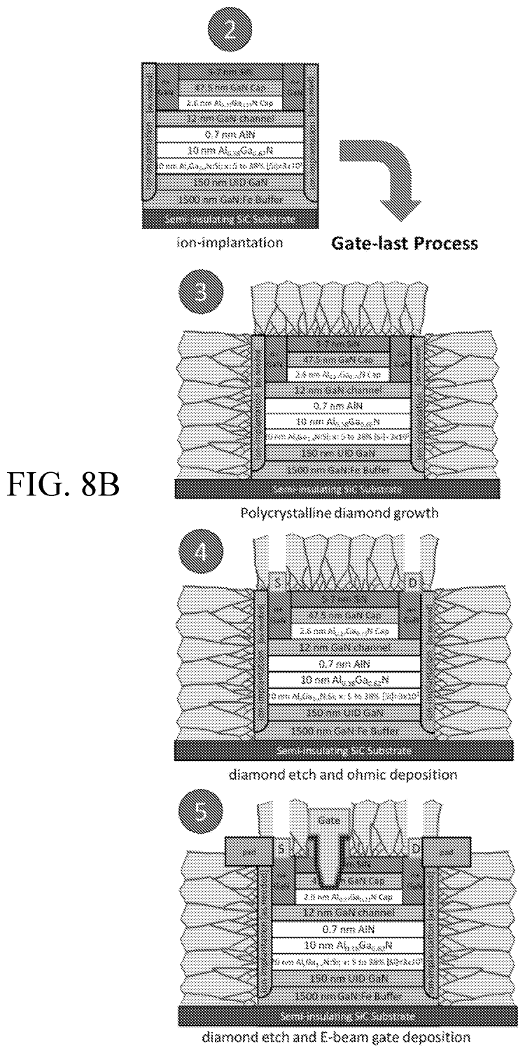

FIGS. 8A and 8B are flow diagrams respectively showing manufacturing steps for specific experimental examples of manufacturing 3D heat-sinking structures according to the present disclosure. FIG. 8A illustrates an exemplary device-first (diamond-last) process, whereas FIG. 8B illustrates an exemplary device-last (diamond-first) process. While any of a variety of materials may be used (depending on the specific type of transistor and/or active area), as exemplary material layers (and respective dimensions) for each of the device active areas in FIGS. 8A and 8B, the specific experimental examples included the following layers, starting and grown up from the substrate layer in order: SiC substrate; 1500 nm GaN: Fe buffer; 150 nm UID GaN; 20 nm AlGa N: Si x: 5 to 38%; 10 nm Al GaN; 0.7 nm AlN; 12 nm GaN channel; 0.6 nm AAlGaN Cap; 47.5 nm GaN Cap; and as the top layer 5-7 nm SiN.

The devices manufactured using these exemplary processes of FIGS. 8A and 8B resemble the devices shown and previously discussed in connection with FIGS. 1A and 1B. Ohmic n+ regions are regrown for the contacts (e.g., similar to 133A of FIG. 1A) and MOCVD SiN for a gate insulator (e.g., also as shown under the gate “G” of FIGS. 1A and 1B). Each of the devices may be isolated if using ion implantation in conjunction with an E-Beam gate lithography process, to ensure that the E-Beam gate lithography process will not be conducted on the respective wafer with significant surface topography. For the manufacture of the 3D device, the top and sidewalls may be etched away to provide a deep trench around the device where PC diamond will be grown on top as well as the sidewalls and tied to the SiC, where the heat sink may be located. Deep trench etching is not necessary for a 2D-approach for a device such as in FIG. 1A.

Accordingly, step 1 of FIG. 8A shows an exemplary device-first (a.k.a. gate-first) process for manufacture of a semiconductor device assuming such circuitry as above being built before the device is built and/or diamond is grown on or around the device, whereas immediately adjacent step 1 of FIG. 8A, step 2 of FIG. 8B similarly shows an exemplary device-last (aka gate-last) process for manufacture of a semiconductor device again assuming such circuitry as above is built and/or diamond is grown on or around the device. The respective sets of steps associated with the device-first process of FIG. 8A and the device-last process of FIG. 8B are separated by a vertical dashed line.

Starting with step 1 of FIG. 8A, non-alloyed contacts are deposited onto the n+ regrown contact layers, over which the source(S) and drain (D) are formed as shown in step 3. Sidewalls may be formed, for example, via ion implantation, as needed for conductive paths to access the source and drain regions and/or, during formation of the diamond grains, for interlayer portions to enhance adhesion and to protect the active region. In the case of implanting for one or more interlayer portions, such interlayer structure may be similar to 130A of FIG. 1A, and the sidewalls similar to 132A of FIG. 1A. Next and as shown in step 4, masked-based etching may be performed for formation of the gate (into the GaN channel) and ion implantation on an as-needed basis is provided on either side of the wafer. Step 5 shows the PC diamond (grains) being grown on the top and sides of the wafer. Step 6 shows the diamond being etched for access of the previously-formed gate and formation of the pads for accessing the source and drain.

In FIG. 8B, step 2 shows the same structure as in step 3 of FIG. 8A but without the source(S) and drain (D) being formed. Step 3 shows the PC diamond (grains) being grown on the top and sides of the wafer. Step 4 of FIG. 8B shows the diamond being etched for exposing the n+ GaN contacts upon which the source and drain are deposited and formed. Step 5 of FIG. 8B shows the same structure after the diamond is etched and the gate is formed by E-beam gate deposition. The structure in step 5 of FIG. 8B also shows the pads being formed through the previously-etched areas for access of the source and drain.

Accordingly, the result of both manufacturing processes of FIGS. 8A and 8B realize a transistor (e.g., in this experimental example a GaN HEMPT type) having an integral 3D thermal heat sink for heat extraction, with the heat being transferred to the (semi-insulating) SiC substrate. The impact of 3D thermal heat sink includes: the additional 3D thermal extraction pathway provided by the diamond deposited in close proximity of the channel and connected to the Si substrate by the wrap-around integration around the active area's perimeter; and a unique benefit provided by effective “thermal field plate” realized by the high-isotropic conductivity of the diamond. Experimentation in connection with the present disclosure verifies that the high heat flux density generated in the hot spot in lateral power devices can be reduced significantly by the heat spreading properties of the isotropic diamond layer in close proximity (within a range of from 2 nm to 50 nm) of the hot spot in the channel, as above in connection with the plots of FIG. 5D.

As may be appreciated by the illustrations in FIGS. 8A and 8B, the semiconductor devices may include a first interlayer portion and one or multiple semiconductor layers as part of the active region wherein the first interlayer portion and the one or multiple semiconductor layers have a stacked formation, and the device may also include a second interlayer sidewall portion oriented along at least one side of the one or multiple semiconductor layers, wherein the first interlayer portion and the second sidewall interlayer portion are to enhance adhesion of the layer of polycrystalline-diamond grains. Further, as shown the gate may extend through a via, defined by etched TFP sidewalls (etched diamond sidewalls manifesting during the etching process), towards or into the active region.

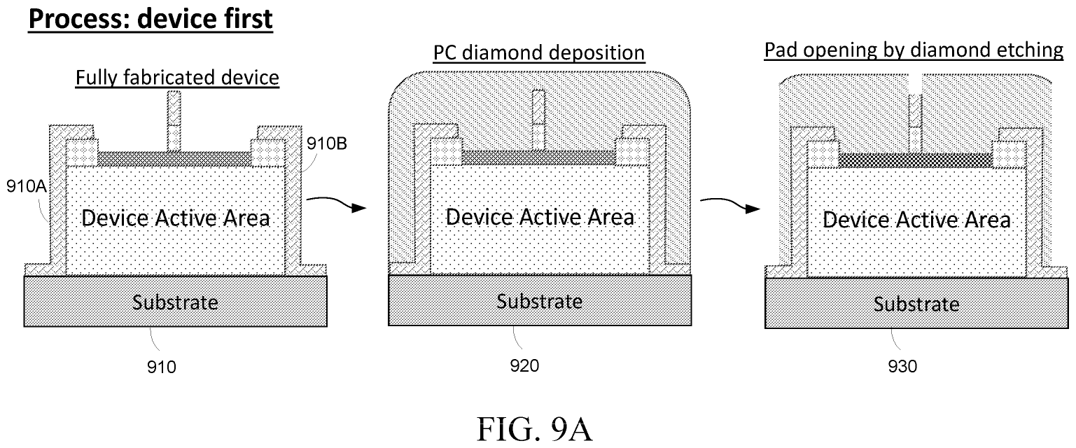

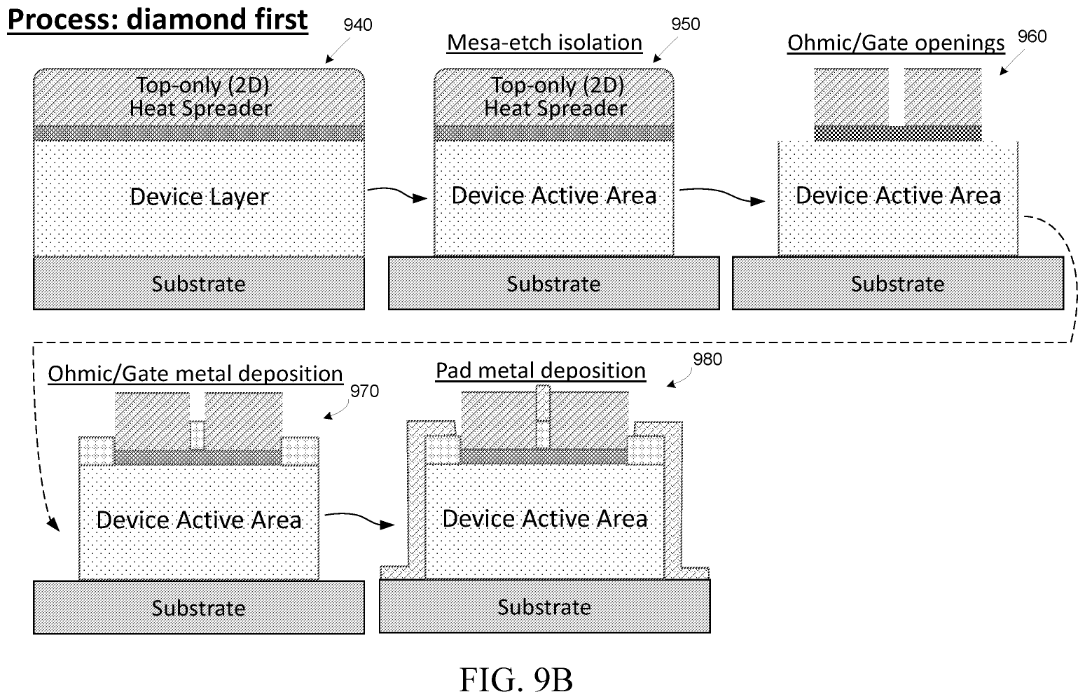

FIGS. 9A and 9B are more generalized flow diagrams which should be readily apparent from the specific exemplary experimental processes depicted in FIG. 8A and in FIG. 8B. FIG. 9A effectively shows a more generalized flow (device-first processing) corresponding to the specific exemplary experimental process of FIG. 8A, whereas FIG. 9B effectively shows a more generalized flow (device-last processing) corresponding to the specific exemplary experimental process of FIG. 8B but as a 2D heat-spreading device.

More specifically, the generalized flow diagram of FIG. 9A shows a 3D heat-spreading device-first process in three steps, step 910, step 920, and step 930. At step 910, a fully-fabricated device is shown as including all aspects except the PC-grown diamond-based thermal field plate. At step 920, the same fully-fabricated device is shown except now including the PC-grown diamond-based thermal field plate. Finally, at step 930, this fully-fabricated device is shown with access to the device's gate being provided by diamond etching. Access to the source and drain areas may be also provided by diamond etching from above or by way of conductive paths 910A and 910B being formed before step 920, as in FIG. 8A.

The flow diagram of FIG. 9B shows the generalized diamond-first (or device-last) process for a 2D heat-spreading device in several steps. Beginning with step 940, a partially-fabricated device is shown as including all aspects (except the gate and S/D terminals) with the PC-grown diamond-based thermal field plate in its 2D configuration along the top (over a protective interlayer). Step 950 depicts the same device except now being prepared for etching of the upper diamond (mesa) layer, such as by an etch masking step, whereby the upper diamond layer corresponds to the PC-grown diamond-based thermal field plate. Step 960 shows the device after diamond etching, with openings for the gate and pads. Step 970 shows the device after a conventional step of ohmic/gate metal deposition through the etch-exposed openings. As a last step 980, the device is shown after metal deposition to form the gate and conductive paths along the sidewalls to access the source and drain.

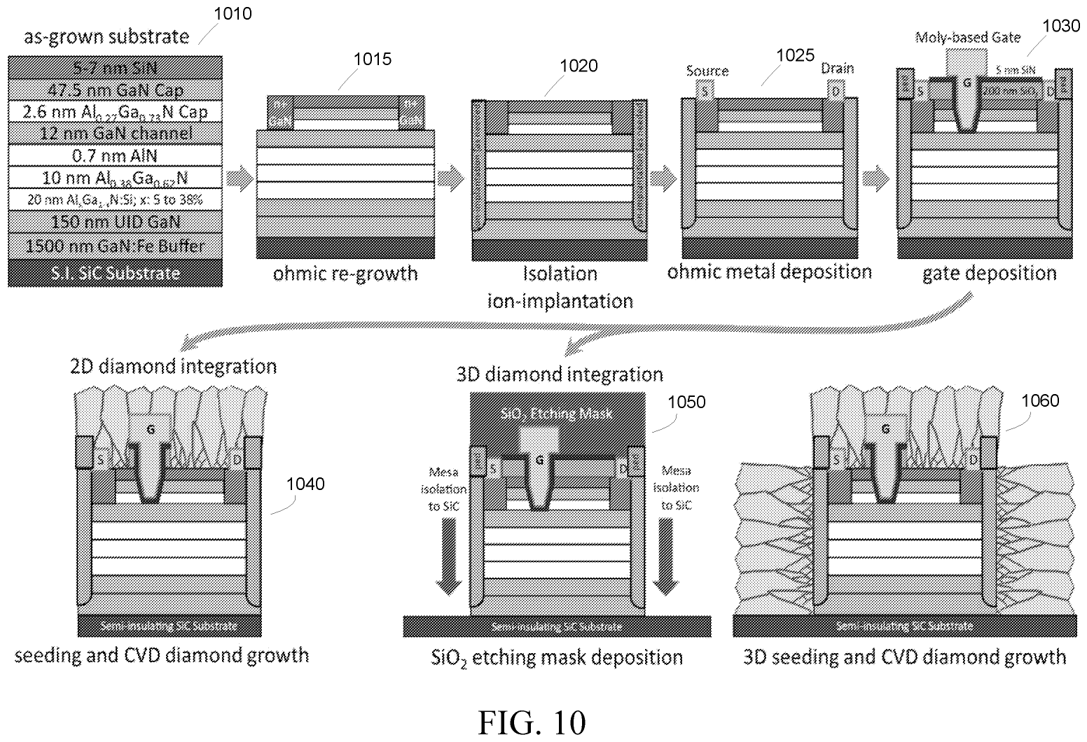

FIG. 10 is another flow diagram showing exemplary manufacturing flow for both a 2D heat-spreading device and a 3D heat-spreading device, also in accordance with the present disclosure. The flow starts with at step 1010 with the device shown including several material-specific layers, such as previously exemplified from an SiC substrate as the bottom layer up to the GaN channel, two cap layers over the GaN channel, and an interlayer (e.g., 5-7 nm of SiN) shown on top of the upper cap layer. Step 1015 shows the device with ohmic re-growth used to form n+ GaN contact layers at respective ends of the interlayer. Step 1020 shows as needed isolation, beyond the interlayer, by way of ion implantation along the sidewalls of the device. Step 1025 shows the device after forming the source and drain by way of ohmic/metal deposition. Step 1030 shows the device after etching and metal deposition for the gate (and also showing SiO2 and SiN for device protection while etching the diamond).

From step 1030, flow proceeds to step 1040 for completing a 2D heat-spreading device and to step 1050 for completing a 3D heat-spreading device. At step 1040, the device is shown after 2D seeding and the ensuing PC CVD diamond growth. For completing a 3D heat-spreading device, from step 1030 flow proceeds to step 1050 at which the device is shown after an SiO₂-tching-mask deposition step over the top of the device and with the sidewall mesas being isolated towards or to the SiC substrate. At step 1060, the device is shown after 3D seeding and the ensuing PC CVD diamond growth.

As shown by way of certain of the experimental examples discussed herein, the present disclosure has demonstrated successful heat removal by way of: 1) a low TBR between the source of heat and the heat spreader; 2) a low thermal resistance path to a heat-sink; and 3) the positioning of the heat-sink maintained at a constant low temperature. In connection with these experiments, while realizing the first of these attributes it has been observed that the other two attributes are interlinked for which establishing the efficacy of a top side diamond integration at the device level measurements is harder, without also characterizing an appropriate packaging scheme. In one such packaging scheme according to an example of the present disclosure, a top side integration will seem to benefit from a flip chip packaging. With such approaches, however, the ultimate effectiveness is nuanced due to the inherent thermal resistance associated with the flip-chip package itself.

Another observation, as observed in connection with the present disclosure, is the importance of in-plane thermal conductivity. The isotropy of the diamond grains reduces the number of grain boundaries in the lateral direction, enabling efficient heat transfer through the spread into the sink. As disclosed herein, in connection with examples of the present disclosure it has been found that diamond grains may be grown and formed with a degree of isotropy to realize the reduction in the number of grain boundaries by growing and forming the diamond grains to reduce the phonon scattering sites (or grain boundaries) as generally depicted in FIGS. 1A, 1B, 8A and 8B. By reducing grain boundaries in this manner, corresponding higher in-plane thermal conductivity is realized, as compared to more typical levels of isotropy from which grains are typically formed using relatively low lateral growth rates.

Accordingly, growing and using diamond for spreading heat in semiconductor devices, according to example aspects and examples of the present disclosure, is believed to advantage many applications and types of semiconductor devices by significantly reducing temperatures in and around their hot spots or channel regions, and such applications and types of semiconductor devices are not limited to those implemented to current device-fabrication platforms and/or the experimental examples described herein. Certain of these experimental examples have focused on GaN-type transistor devices and HEMPTs in light of their high-power output (Pout) per element which results in severe to moderate heat challenges. In these and other types of active devices, as their operational frequencies increase, the associated gain becomes an important factor. Therefore, any heat removal to maintain power-added efficiency (PAE) may become critical. This follows as heat generated within the device limits the Pout and the device efficiency, because it triggers a vicious cycle. Heat dissipation causes channel mobility to decrease and this in turn increases the knee voltage of the device (decreasing drain efficiency) and also decreasing gain (decreasing PAE) and the cycle continues. When PAE gets lower, in order to maintain the same amount of Pout, the drain voltage may be increased. However, to the extent this can be done while maintaining the impedances required for optimal power transfer, it can trigger dispersion which causes knee walk out and lowers efficiency again. To break this loop, removal of heat is believed to be important, especially for devices operating at high frequencies.

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisional Application.

The skilled artisan would recognize the various contexts and terminology as used in the present disclosure. As examples, the Specification may describe and/or illustrates aspects useful for implementing the examples by way of various semiconductor materials/circuits which may be illustrated as or using terms such as stages of manufacturing semiconductive devices, aspects and terms relating to diamond growth processing beginning with seeding and nucleation, and various terms including layers, blocks, modules, device, system, unit, controller, and/or other circuit-related or material-type depictions. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. It would also be appreciated that terms to exemplify orientation, such as upper/lower, left/right, top/bottom, over/under, above/below, etc., may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

What is claimed:

1. A semiconductor device comprising:
a circuit including an active region; and
a thermal field plate (“TFP”) having a first portion oriented over or under the active region, the first portion:
being located in proximity to the active region for passing heat away from the active region, and
including a layer of polycrystalline-diamond grains with an average grain width dimension and an average thickness dimension, wherein the average grain width dimension and the average thickness dimension characterize the polycrystalline-diamond grains as being more isotropic than columnar.

2. The semiconductor device of claim 1, further including an interlayer being located between the active region and the first portion of the TFP, wherein the interlayer includes a dielectric material, and wherein the average grain width dimension is closer to the average thickness dimension than to twice the average thickness dimension.

3. The semiconductor device of claim 1, wherein the average grain width dimension is in a direction parallel to a first plane in which the first portion of the TFP and a layer of the active region are commonly oriented, and wherein the average thickness dimension is in an orthogonal direction relative to the first plane, and the average grain width and average thickness dimensions characterize the layer of polycrystalline-diamond grains as approaching an ideal anisotropy ratio.

4. The semiconductor device of claim 1, wherein the average thickness dimension to the average grain width dimension characterizes an anisotropy ratio of the polycrystalline-diamond grains as having an anisotropy ratio that is within approximately twelve percent of unity.

5. The semiconductor device of claim 1, further including an interlayer being located between the active region and the first portion of the TFP, and interlayer is to protect the active region.

6. The semiconductor device of claim 1, further including an interlayer being located between the active region and the first portion of the TFP, and interlayer is to enhance adhesion of the layer of polycrystalline-diamond grains.

7. The semiconductor device of claim 1, further including an interlayer being located between the active region and the first portion of the TFP, and interlayer is to protect the active region while the layer of polycrystalline-diamond grains are being formed and to enhance adhesion of the layer of polycrystalline-diamond grains.

8. The semiconductor device of claim 1, wherein the first portion of the TFP is located within 2-50 nm from the active region.

9. The semiconductor device of claim 1, further including an interlayer between the active region and the first portion of the TFP, and a substrate adjacent the active region along a side of the active region that is opposite the interlayer.

10. The semiconductor device of claim 1, further including a substrate adjacent the active region along a side of the active region that is opposite the first portion of the TFP, wherein the substrate includes one or a combination of: silicon, or GaN, or Ga₂O₃, and InP.

11. The semiconductor device of claim 1, wherein the layer of polycrystalline-diamond grains are formed to set, during operation of the transistor, a degree of thermal conductivity or of thermal boundary resistance, which is dependent on the polycrystalline-diamond grains as being more isotropic than columnar.

12. The semiconductor device of claim 1, further including a transistor having a gate adjacent the active region and having source and drain regions which are to operate in response to energy applied to the gate.

13. The semiconductor device of claim 1, including an interlayer located between the active region and the first portion of the TFP, and including a transistor having source and drain regions and having a gate extending through the first portion of the TFP and extending towards or into the active region through a via in the interlayer.

14. The semiconductor device of claim 1, including an interlayer, located between the active region and the first portion of the TFP, to pass heat from the active region by passing heat in a direction that is orthogonal to a plane along which the interlayer is situated.

15. The semiconductor device of claim 1, including an interlayer portion that is to enhance adhesion of the layer of polycrystalline-diamond grains and further including one or multiple semiconductor layers that form at least part of the active region, wherein the interlayer portion and the one or multiple semiconductor layers have a stacked formation.

16. The semiconductor device of claim 1, including a first interlayer portion and including one or multiple semiconductor layers as part of the active region, wherein the first interlayer portion and the one or multiple semiconductor layers have a stacked formation, and further including a second interlayer sidewall portion oriented along at least one side of the one or multiple semiconductor layers, wherein the first interlayer portion and the second sidewall interlayer portion are to enhance adhesion of the layer of polycrystalline-diamond grains.

17. The semiconductor device of claim 1, wherein each of the first portion and the active region are oriented along a direction characterized by an X-Y plane and with the polycrystalline-diamond grains of the first portion of polycrystalline-diamond grains being more isotropic than columnar to minimize grain boundaries between the polycrystalline-diamond grains.

18. The semiconductor device of claim 1, wherein the TFP includes a first TFP section oriented along a direction characterized by a first plane and a second TFP section having a second portion, wherein the first portion is part of a first TFP section, the second TFP section is oriented along a direction characterized by a second plane that is different than the first plane, and for the first portion and the second portion, polycrystalline-diamond grains are more isotropic than columnar to minimize reduce grain boundaries between the polycrystalline-diamond grains.

19. The semiconductor device of claim 1, wherein the first portion is oriented along a direction characterized by an X-Y plane to maximize in-plane thermal conductivity, during operation of the circuit.

20. The semiconductor device of claim 1, wherein the circuit includes a transistor with source and drain regions and with a gate extending through a via, defined by etched TFP sidewalls, towards or into the active region.

21. The semiconductor device of claim 1, wherein the circuit includes a transistor with source and drain regions and with a gate extending through a via towards or into the active region, wherein the via is defined by polycrystalline-diamond grains, from among the layer of polycrystalline-diamond grains, formed around the gate.

22. A semiconductor device comprising:
a circuit including an active region having one or multiple semiconductor layers, and including a gate extending towards or into the active region and further including source and drain regions on either side of the active region;
an upper interlayer section over the active region and oriented with the one or multiple semiconductor layers being arranged as a stack of layers with each of the layers being oriented along a common first plane;
at least one sidewall interlayer section respectively located along at least one side of the one or multiple semiconductor layers and oriented along another plane that intersects the common first plane; and
a thermal field plate (“TFP”) having a top TFP section adhered to the upper interlayer section and at least one side TFP section respectively adhered to the at least one sidewall interlayer section, wherein each of the top TFP section and the at least one side TFP section
being located in proximity to the active region for passing heat away from the active region, and
including a layer of polycrystalline-diamond grains with an average grain width dimension and an average thickness dimension which dimensions characterize the polycrystalline-diamond grains as being shaped to maximize, during operation of the circuit, in-plane thermal conductivity by the upper interlayer section along the common first plane and by the sidewall interlayer section along the other plane.

23. The semiconductor device of claim 22, wherein each of the upper interlayer section and the sidewall interlayer section are to enhance adhesion of the polycrystalline-diamond grains.

24. The semiconductor device of claim 22, further including a substrate over which the circuit is situated, wherein the at least one sidewall interlayer section is to enhance adhesion of the polycrystalline-diamond grains and to pass the heat away from the active region and towards the substrate.

25. The semiconductor device of claim 22, wherein during the operation of the circuit, the TFP controls high-heat flux density linked to heat generated from a region around the channel.

26. The semiconductor device of claim 22, wherein the circuit includes a power amplifier.

27. The semiconductor device of claim 22, wherein the circuit includes a high-frequency high-power (HFHP) transistor, and the active region is part of the HFHP transistor.

28. The of claim 22, wherein diamond grains, from among the diamond grains of the TFP in at least one of the upper interlayer section and the sidewall interlayer section, are located within 2-50 nm of the active region.

29. A method comprising:
passing heat away from an active region of a circuit by using a thermal field plate (“TFP”) having a first portion oriented along a first plane relative to the active region, the first portion
being located in proximity to the active region for passing heat away from the active region,
including a layer of polycrystalline-diamond grains with an average grain width dimension in a direction parallel to the first plane and an average thickness dimension in an orthogonal direction relative to the first plane, wherein the average grain width dimension and the average thickness dimension characterize the polycrystalline-diamond grains as being more isotropic than columnar.
